(19) United States
(12) Patent Application Publication
(10) Pub. No.: US 2026/0076003 A1
(43) Pub. Date: Mar. 12, 2026

(54) DISPLAY DEVICE INCLUDING PLURALITY OF LED MODULES

(71) Applicants: Min Seon KIM, Hwaseong-si (KR); Global Technologies Co., Ltd., Hwaseong-si (KR)

(72) Inventors: Yong Geun KIM, Hwaseong-si (KR); Gea Ok CHO, Hwaseong-si (KR); Min Seon KIM, Hwaseong-si (KR)

(21) Appl. No.: 19/392,088

(22) Filed: Nov. 17, 2025

Related U.S. Application Data
(63) Continuation-in-part of application No. PCT/KR2024/006523, filed on May 14, 2024.

(30) Foreign Application Priority Data
Jun. 8, 2023 (KR) 10-2023-0073824

(51) Int. Cl. H10H 29/24; H10H 29/80

(52) U.S. Cl. CPC H10H 29/24; H10H 29/922

(57) ABSTRACT

A display device includes a plurality of first LED modules, each including an LED array in which U×V LEDs are arranged, and a plurality of second LED modules, each including an LED array in which M×N LEDs are arranged, wherein each of the plurality of first LED modules includes a driving chip, and wherein at least some of the driving chips provided in the plurality of first LED modules drive an LED array included in a corresponding first LED module and LED arrays included in K second LED modules.

### BACKGROUND OF THE INVENTION

### Field of the Invention

The present disclosure relates to a display device including a plurality of LED modules.

### Description of the Related Art

A micro-LED display is one of the latest display technologies that forms a screen by using small and flexible micro-LED chips. The micro-LED display is manufactured by a micro-LED chip manufacturing step, an LED-array formation step, and a display-panel manufacturing step.

Specifically, the micro-LED chip is manufactured through a semiconductor process, a plurality of micro-LED chips are assembled to form an LED array, and the LED array is used to manufacture an actual display panel.

However, when forming an LED array, it is necessary to optimize an arrangement of a driving chip that drives each LED.

### BACKGROUND ART DOCUMENT

Patent Document 1: Korean Patent Application Publication No. 10-2018-0119273, “Micro LED Display Apparatus And Method For Fabricating The Same” (published on Nov. 2, 2018).

### SUMMARY OF THE INVENTION

An object of the present disclosure is to provide a display device including a plurality of LED modules that can reduce cost by optimizing an arrangement of a driving chip for driving LEDs.

A LED display device comprises a plurality of first LED modules, each including an LED array in which U×V LEDs are arranged, and a plurality of second LED modules, each including an LED array in which M×N LEDs are arranged, wherein each of the plurality of first LED modules includes a driving chip within a package of the corresponding first LED module, or includes the driving chip housed in a package of the driving chip that is separate from the corresponding first LED module and in contact with a bottom surface that is a lower portion of the corresponding first LED module, wherein at least some of the driving chips provided in the plurality of first LED modules each drive an LED array included in a corresponding first LED module and LED arrays included in K second LED modules, wherein each of the K second LED modules is arranged adjacent to one of a plurality of sides of a package of the corresponding first LED module or a package of the corresponding driving chip, wherein U, M, V, and N are each a natural number equal to or greater than 5, wherein U and M are equal to or different from each other, wherein V and N are equal to or different from each other, and wherein K is a natural number equal to or greater than 1.

A LED display device according to embodiments includes a plurality of first LED modules, each including an LED array in which U×V LEDs are arranged, and a plurality of second LED modules, each including an LED array in which M×N LEDs are arranged, wherein U, M, V, and N are each a natural number equal to or greater than 5, wherein U and M are equal to or different from each other, and wherein V and N are equal to or different from each other.

Moreover, each of the plurality of first LED modules includes a driving chip, and at least some of the driving chips provided in the plurality of first LED modules drive an LED array included in a corresponding first LED module and LED arrays included in K second LED modules, where K is a natural number equal to or greater than 1.

In addition, a package of the first LED module or a package of the driving chip includes, in a plan view, a rectangular shape with four sides, and includes M pins for outputting M row-scan switch signals and K×N pins for outputting K×N column driving signals on a bottom surface.

The package of the first LED module or the package of the driving chip is configured such that an average of distances to one side is a smallest among averages of distances between the M pins and each of the four sides. In addition, an average of distances to another side is a smallest among averages of distances between N pins for outputting first N column driving signals among the K×N pins and each of the four sides.

Each of the K second LED modules is arranged adjacent to one of a plurality of sides of a package of the corresponding first LED module or a package of the corresponding driving chip.

In addition, each of the plurality of second LED modules has a rectangular shape in a plan view, and includes M pins for receiving M row-scan switch signals and N pins for receiving N column driving signals.

In the LED display device according to a first embodiment, U and M are equal to each other, V and N are equal to each other, and each of the plurality of first LED modules and each of the plurality of second LED modules have an identical external appearance in a top view.

Moreover, in a top view of the LED display device according to embodiments, a size of each of the plurality of first LED modules corresponds to 1 time or Y times a size of each of the plurality of second LED modules, where Y is a natural number equal to or greater than 2.

Each of the K second LED modules is arranged adjacent to the corresponding first LED module, and the LED display device is configured such that a group unit including the corresponding first LED module and the K second LED modules is repeatedly arranged in the form of a block.

In addition, in the LED display device according to a first embodiment to a second embodiment, the group unit including the corresponding first LED module and the K second LED modules is repeatedly arranged in the shape of the English alphabet capital letter “T”or “T”rotated 180 degrees.

According to a display device including a plurality of LED modules, it is possible to reduce cost by optimizing an arrangement of a driving chip that drives LEDs.

### BRIEF DESCRIPTION OF THE DRAWINGS

FIG. 1 is an exemplary view illustrating an arrangement of a display device including a plurality of LED modules in a top view according to a first embodiment.

FIG. 2 is an explanatory view illustrating an arrangement of the plurality of LED modules in the display device according to the first embodiment.

FIG. 3 is an explanatory view illustrating a configuration of a first LED module in the display device according to the first embodiment.

FIG. 4 is an explanatory view illustrating a configuration of a second LED module in the display device according to the first embodiment.

FIG. 5 is an explanatory view illustrating an arrangement of a package of a first LED module when a driving chip is embedded in the display device according to the first embodiment.

FIG. 6 is an explanatory view illustrating an arrangement of a package of a second LED module in the display device according to the first embodiment.

FIG. 7 is a first explanatory view of driving a driving chip according to the first embodiment.

FIG. 8 is a second explanatory view of driving a driving chip according to the first embodiment.

FIG. 9 is an exemplary view illustrating an arrangement of a display device including a plurality of LED modules in a top view according to a second embodiment.

FIG. 10 is an explanatory view illustrating an arrangement of the plurality of LED modules in the display device according to the second embodiment.

FIG. 11 is an explanatory view illustrating an arrangement of the plurality of LED modules in the display device according to a third embodiment.

### DETAILED DESCRIPTION OF THE INVENTION

Hereinafter, a display device including a plurality of LED modules according to embodiments of the present disclosure will be described in detail with reference to the accompanying drawings. The following embodiments of the present disclosure are intended only to embody the present disclosure and do not limit the scope of rights of the present disclosure. Variations that can be easily inferred by a person skilled in the art to which the present disclosure belongs from the detailed description and embodiments of the present disclosure are interpreted as being within the scope of rights of the present disclosure.

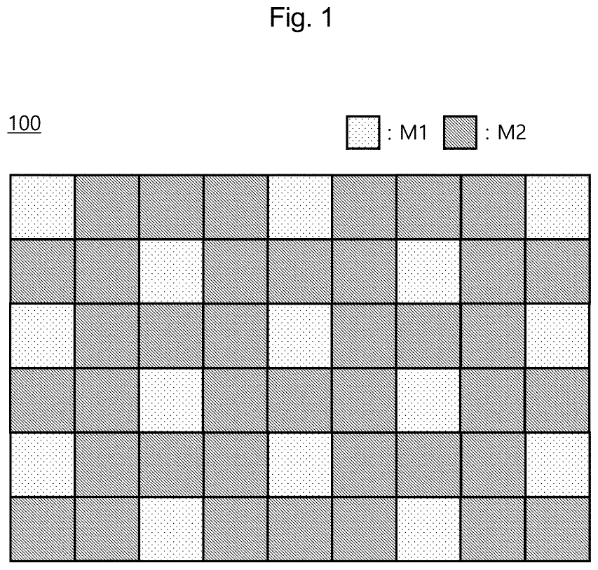

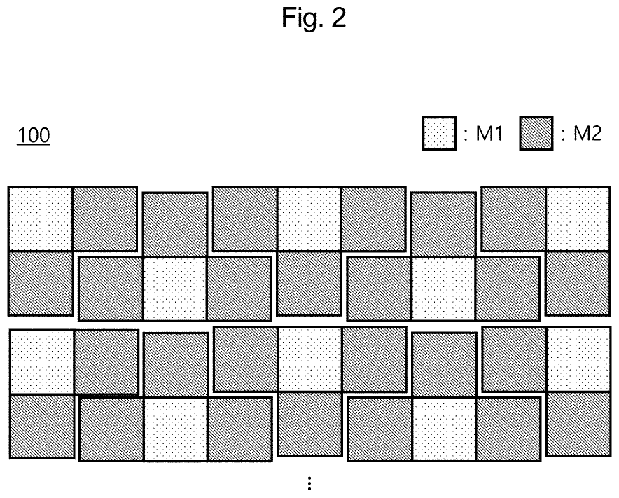

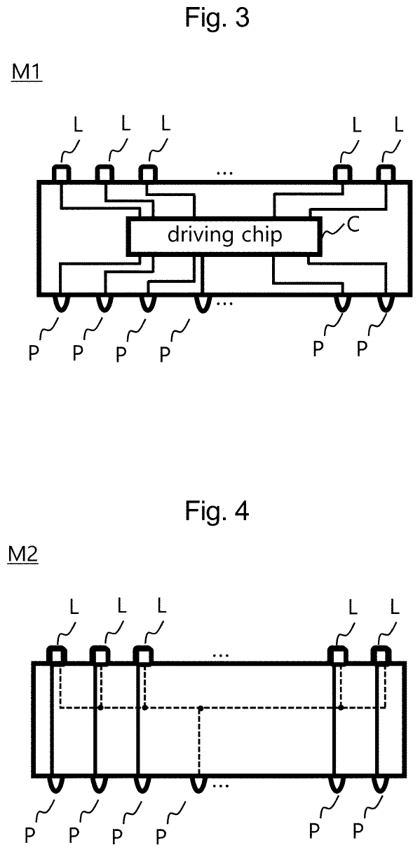

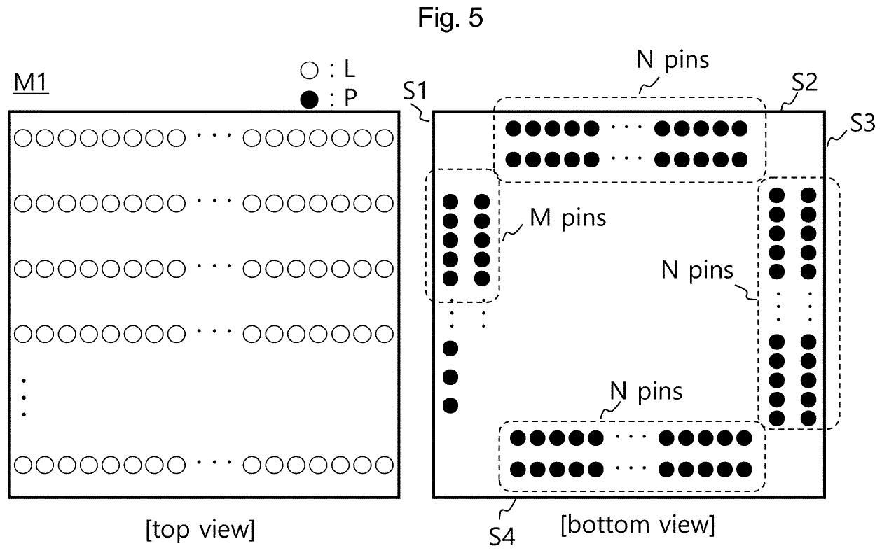

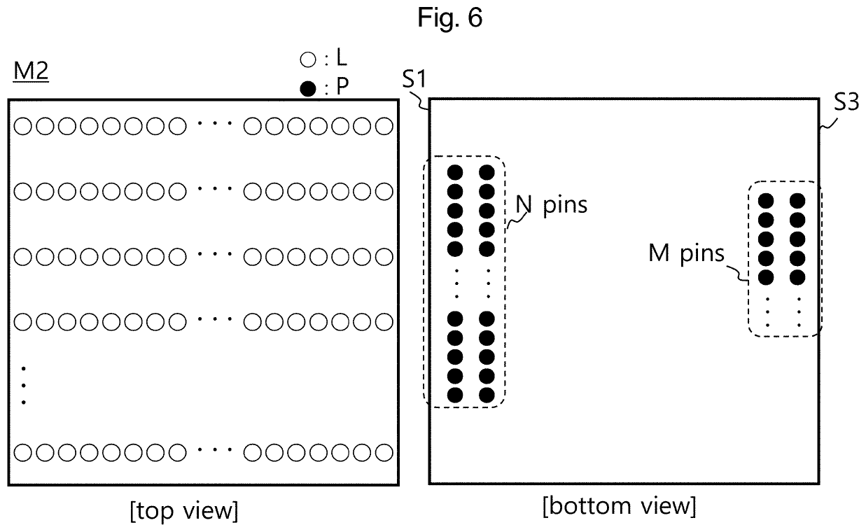

First, FIG. 1 is an exemplary view illustrating an arrangement of a display device 100 including a plurality of LED modules (M1, M2) in a top view according to the first embodiment. FIG. 2 is an explanatory view illustrating an arrangement of the plurality of LED modules (M1, M2) according to the first embodiment. In addition, FIG. 3 and FIG. 4 are explanatory views illustrating a configuration of a first LED module (M1) and a configuration of a second LED module (M2), respectively, according to the first embodiment. FIG. 5 and FIG. 6 are explanatory views illustrating an arrangement of a package of the first LED module (M1) and an arrangement of a package of the second LED module (M2), respectively, when a driving chip (C) is embedded in the display device 100 according to the first embodiment.

The display device 100 according to the first embodiment includes a plurality of first LED modules, each including an LED array in which U×V LEDs are arranged, and a plurality of second LED modules, each including an LED array in which M×N LEDs are arranged. Each of the plurality of first LED modules includes a driving chip within a package of the corresponding first LED module, or includes the driving chip housed in a package of the driving chip that is separate from the corresponding first LED module and in contact with a bottom surface that is a lower portion of the corresponding first LED module. At least some of the driving chips provided in the plurality of first LED modules each drive an LED array included in a corresponding first LED module and LED arrays included in K second LED modules. Each of the K second LED modules is arranged adjacent to one of a plurality of sides of a package of the corresponding first LED module or a package of the corresponding driving chip. Here, U, M, V, and N are each a natural number equal to or greater than 5, U and M are equal to or different from each other, V and N are equal to or different from each other, and K is a natural number equal to or greater than 1.

The display device 100 according to the first embodiment will be described with reference to FIGS. 1 to 6.

The display device 100 according to the first embodiment includes a substrate (not shown) and a plurality of LED modules (M1, M2) arranged in a matrix shape consisting of a plurality of rows and a plurality of columns.

The plurality of LED modules (M1, M2) includes a plurality of first LED modules (M1) and a plurality of second LED modules (M2). In addition, a top surface of each of the plurality of first LED modules (M1) includes an LED array in which U×V LEDs (L) are arranged, and a top surface of each of the plurality of second LED modules (M2) includes an LED array in which M×N LEDs (L) are arranged. Each of the plurality of first LED modules (M1) and each of the plurality of second LED modules (M2) have an identical external appearance in a top view. Accordingly, a size of each of the plurality of first LED modules (M1) corresponds to the size of each of the plurality of second LED modules (M2). That is, U and M are equal to each other, and V and N are equal to each other. Here, U, M, V, and N are each a natural number equal to or greater than 5.

However, each of the plurality of first LED modules (M1) includes a driving chip (C) capable of driving an LED array included in the corresponding first LED module (M1) and LED arrays included in K second LED modules (M2), where K is a natural number equal to or greater than 1. By sharing one driving chip (C) among the corresponding first LED module (M1) and the K second LED modules (M2), the integration density of the driving chip (C) can be improved and overall cost can be reduced.

For example, the driving chip (C) provided in a first LED module (M1) located in the middle drives the LED array included in the first LED module (M1) and the LED arrays included in the K second LED modules (M2), and the driving chip (C) provided in a first LED module (M1) located at an edge drives the LED array included in the first LED module (M1) and LED arrays included in fewer than K second LED modules (M2). That is, in FIGS. 1 and 2, the driving chip (C) drives the LED array included in the corresponding first LED module (M1) and the LED arrays included in three or two second LED modules (M2). In summary, at least some of the driving chips (C) drive the LED array included in the corresponding first LED module (M1) and the LED arrays included in the K second LED modules (M2), and at least some other driving chips (C) drive the LED array included in the corresponding first LED module (M1) and LED arrays included in fewer than K second LED modules (M2).

In other words, at least some of the plurality of first LED modules (M1) are provided with a driving chip (C) that drives the LED array included in the corresponding first LED module (M1) and the LED arrays included in the K second LED modules (M2), and at least some other first LED modules (M1) are provided with a driving chip (C) that drives the LED array included in the corresponding first LED module (M1) and LED arrays included in fewer than K second LED modules (M2).

The driving chip (C) is embedded in the corresponding first LED module (M1) and is provided in an integrated form within the package of the first LED module (M1). Alternatively, the driving chip (C) is housed in a separate package and is provided in the first LED module (M1) in contact with a bottom surface, which is a lower portion of the corresponding first LED module (M1).

The substrate is a multilayer printed circuit board and is formed to have a size corresponding to the overall size of the plurality of LED modules (M1, M2), which are light-emitting surfaces of the display device 100. Moreover, the substrate is disposed below the plurality of first LED modules (M1), the driving chip (C), and the plurality of second LED modules (M2) to connect pins (P) on the bottom surface of the plurality of first LED modules (M1) and the plurality of second LED modules (M2) to each other, or to connect pins (P) on the bottom surface of the driving chip (C) and the plurality of second LED modules (M2) to each other. That is, the substrate serves to connect the plurality of first LED modules (M1), the driving chip (C), the plurality of second LED modules (M2), and an external signal to one another. The pins (P) are also referred to as terminals.

Each of the K second LED modules (M2) is arranged adjacent to the corresponding first LED module (M1).

Moreover, in the LED display device 100 according to the first embodiment, a group unit including the first LED module (M1) and the K second LED modules (M2) is repeatedly arranged in the form of a block. For example, the group unit including the corresponding first LED module (M1) and the K second LED modules (M2) is repeatedly arranged in the shape of the English alphabet capital letter “T” or “T” rotated 180 degrees.

That is, in the LED display device 100 according to the first embodiment, group units each including the corresponding first LED module (M1) and K second LED modules (M2) are arranged like fitting puzzle pieces together.

The package of the first LED module (M1) when the driving chip (C) is embedded or the package of the driving chip (C) when the driving chip (C) is housed in a separate package has a rectangular shape with a first side (S1) to a fourth side (S4) in a plan view, and includes M pins (P) for outputting M row-scan switch signals and K×N pins (P) for outputting K×N column driving signals on a bottom surface. Moreover, the package of the first LED module (M1) when the driving chip (C) is embedded or the package of the driving chip (C) when the driving chip (C) is housed in a separate package may further include pins (P) other than the M pins (P) and the K×N pins (P).

For reference, the first side (S1) to the fourth side (S4) may be named sequentially, but in some cases, the four sides of the rectangular shape may be named randomly without any order. That is, the first side (S1) may be referred to as one side, the second side (S2) as another side, the third side (S3) as yet another side, and the fourth side (S4) as the remaining side.

The M pins (P) and the K×N pins (P) on the bottom surface of the package of the first LED module (M1) or the package of the driving chip (C) may be implemented using a ball grid array (BGA) package. That is, when the BGA package is used, the pins (P) take the form of solder balls.

In FIGS. 1 to 8, K is set to 3. M pins (P) for outputting M row-scan switch signals (SIG(S)) are arranged around the first side (S1) of the bottom surface of the package of the first LED module (M1), and N pins (P) are arranged around each of the second side (S2) to the fourth side (S4).

That is, in the package of the first LED module (M1) or in the package of the driving chip (C), the M pins (P) are arranged around the first side (S1) such that an average of distances to the first side (S1) is a smallest among the averages of the distances between the M pins (P) and each of the first side (S1) to the fourth side (S4). Specifically, the distances between each of the M pins (P) and the first side (S1) are calculated, and an average of the calculated distances is smaller than an average of the distances between each of the M pins (P) and the other sides.

Moreover, first N pins (P) for outputting first N column driving signals (SIG(D)) among the K×N pins (P) are arranged around the second side (S2) such that an average of distances to the second side (S2) is a smallest among the averages of distances between the first N pins (P) and each of the first side (S1) to the fourth side (S4).

In addition, second N pins (P) for outputting second N column driving signals (SIG(D)) among the K×N pins (P) are arranged around the third side (S3) such that an average of the distances to the third side (S3) is a smallest among the averages of the distances between the second N pins (P) and each of the first side (S1) to the fourth side (S4).

Third N pins (P) for outputting third N column driving signals (SIG(D)) among the K×N pins (P) are arranged around the fourth side (S4) such that an average of the distances to the fourth side (S4) is a smallest among the averages of the distances between the third N pins (P) and each of the first side (S1) to the fourth side (S4).

In summary, each of the K second LED modules (M2) is arranged adjacent to one of the plurality of sides of the package of the corresponding first LED module (M1) or the package of the corresponding driving chip (C). By this arrangement, wiring between the package of the corresponding first LED module (M1) or the package of the corresponding driving chip (C) and the packages of the K second LED modules (M2) through the substrate can be optimized.

As can be seen from FIG. 6, each of the plurality of second LED modules (M2) has a rectangular shape in a plan view and includes pins (P) for receiving M row-scan switch signals (SIG(S)) and N column driving signals (SIG(D)) on a bottom surface.

For example, the M row-scan switch signals (SIG(S)) and the N column driving signals (SIG(D)) are arranged around opposing sides on the bottom surface of the package of the second LED module (M2) having a rectangular shape.

That is, M pins (P) for receiving the M row-scan switch signals (SIG(S)) are arranged around the third side (S3) such that an average of the distances to the third side (S3) is a smallest among the averages of the distances between the M pins (P) and each of the first side (S1) to the fourth side (S4). In addition, N pins (P) for receiving the N column driving signals (SIG(D)) are arranged around the first side (S1) such that an average of the distances to the first side (S1) is a smallest among the averages of the distances between the N pins (P) and each of the first side (S1) to the fourth side (S4). For reference, the first side (S1) to the fourth side (S4) may be named sequentially, but in some cases, the four sides of the rectangular shape may be named randomly without any order.

Moreover, the package of the second LED module (M2) may further include pins (P) other than the M pins (P) and the N pins (P).

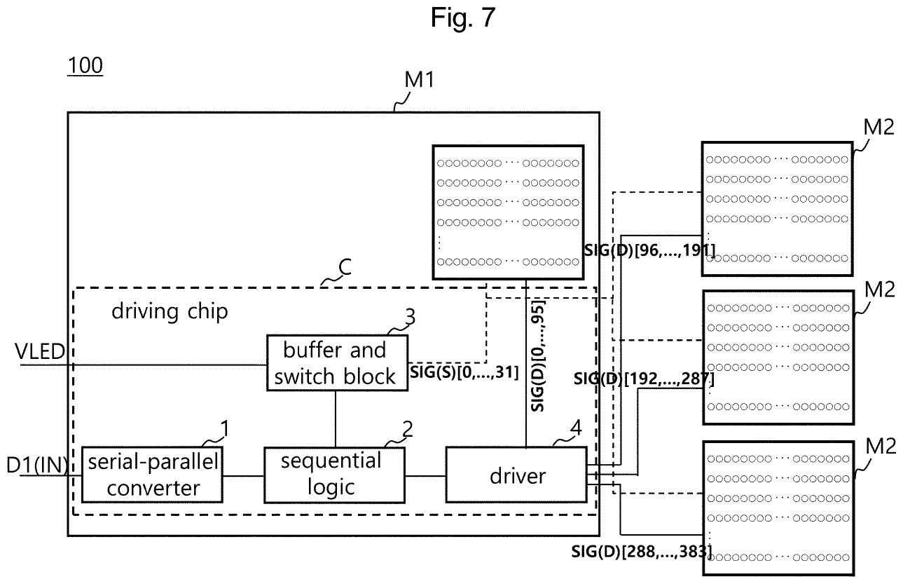

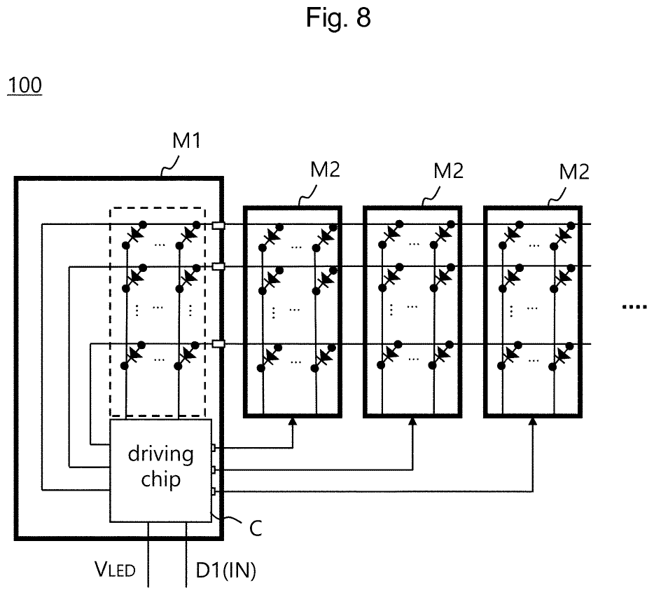

FIGS. 7 and 8 are a first explanatory view and a second explanatory view of driving the driving chip (C) according to the first embodiment, respectively.

As can be seen from FIGS. 7 and 8, the driving chip (C) includes a serial-parallel converter 1 for receiving and parallelizing a first signal (D1(IN)) which is a serial signal, a sequential logic 2 for receiving the signals from the serial-to-parallel converter 1 and separating them into row-scan switch signals (SIG(S)) and column driving signals (SIG(D)) for dimming, a buffer and switch block 3 for receiving the row-scan switch signals (SIG(S)) from the sequential logic 2 and switching and outputting the same, and a driver 4 for receiving and outputting the column driving signals (SIG(D)) from the sequential logic 2. For reference, the first signal (D1(IN)) is output from a controller (not shown), and is transmitted from one driving chip (C) to another driving chip (C) in a daisy chain structure (not shown).

As a result, M row-scan switch signals (SIG(S)) are output from the buffer and switch block 3, and (K+1)×N column driving signals (SIG(D)) are output from the driver 4. The row-scan switch signal (SIG(S)) is applied to a row of the LED array and is also called a row signal or scan signal, and the column driving signal (SIG(D)) is applied to a column of the LED array and is also called a column signal or data signal.

Let M and U be 32, K be 3, and N and V be 96. That is, when each of the first LED module (M1) and the second LED module (M2) is an LED array in which 32×96 LEDs (L) are arranged, a single driving chip (C) can drive the LED array included in the corresponding first LED module (M1) and the three second LED modules (M2).

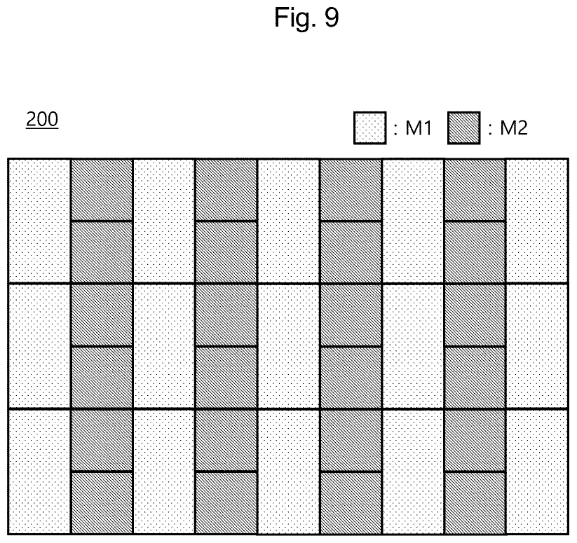

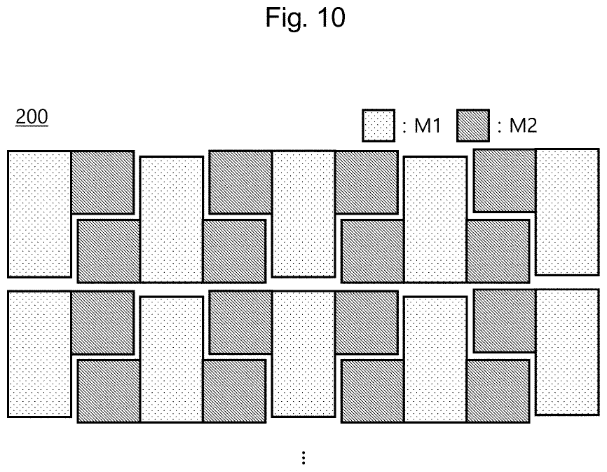

FIG. 9 is an exemplary view illustrating an arrangement of a display device 200 including a plurality of LED modules (M1, M2) in a top view according to a second embodiment. Moreover, FIG. 10 is an explanatory view illustrating an arrangement of the plurality of LED modules (M1, M2) in the display device 200 according to the second embodiment.

The display device 200 including the plurality of LED modules (M1, M2) according to the second embodiment includes the characteristics of the display device 100 including the plurality of LED modules (M1, M2) according to the first embodiment described above, unless otherwise described.

The display device 200 according to the second embodiment includes a substrate (not shown) and a plurality of LED modules (M1, M2) arranged in a matrix shape consisting of a plurality of rows and a plurality of columns. However, in the display device 200 according to the second embodiment, the first LED module (M1) can occupy two or more unit cells in the matrix shape.

The plurality of LED modules (M1, M2) includes a plurality of first LED modules (M1) and a plurality of second LED modules (M2). In addition, a top surface of each of the plurality of first LED modules (M1) includes an LED array in which U×V LEDs (L) are arranged, and a top surface of each of the plurality of second LED modules (M2) includes an LED array in which M×N LEDs (L) are arranged. The plurality of first LED modules (M1) and the plurality of second LED modules (M2) have different external appearances in a top view. That is, at least one of U and M, or V and N is different from the other. Here, U, M, V, and N are each a natural number equal to or greater than 5.

In FIGS. 9 and 10, by way of example, U is twice M, and V and N are equal to each other. In this case, the first LED module (M1) occupies two unit cells of a matrix shape, and the second LED module (M2) corresponds to one unit cell.

That is, in a top view, a size of each of the plurality of first LED modules (M1) corresponds to Y times a size of each of the plurality of second LED modules (M2), where Y is a natural number equal to or greater than 2.

Each of the plurality of first LED modules (M1) includes a driving chip (C) capable of driving an LED array included in the corresponding first LED module (M1) and LED arrays included in K second LED modules (M2), where K is a natural number equal to or greater than 1. By sharing one driving chip (C) among the corresponding first LED module (M1) and the K second LED modules (M2), the integration density of the driving chip (C) can be improved and overall cost can be reduced. For reference, K is exemplified as 2 in FIGS. 9 and 10.

Moreover, at least some of the driving chips (C) drive an LED array included in the corresponding first LED module (M1) and LED arrays included in the K second LED modules (M2), and at least some other driving chips (C) drive an LED array included in the corresponding first LED module (M1) and LED arrays included in fewer than K second LED modules (M2).

The driving chip (C) is embedded in the corresponding first LED module (M1) and is provided in an integrated form within the package of the first LED module (M1). Alternatively, the driving chip (C) is housed in a separate package and is provided in the first LED module (M1) in contact with a bottom surface, which is a lower portion of the corresponding first LED module (M1). However, the driving chip (C) needs to be arranged in a partial area adjacent to the K second LED modules (M2) in the corresponding first LED module (M1). That is, when the corresponding driving chip (C) drives two left and right second LED modules (M2), the driving chip (C) is arranged between the two left and right second LED modules (M2).

Moreover, M pins (P) for outputting M row-scan switch signals (SIG(S)) are arranged around the first side (S1) of the bottom surface of the package of the first LED module (M1), and N pins (P) are arranged around the second side (S2) and the fourth side (S4), respectively. That is, it is not necessary to arrange N pins (P) around the third side (S3).

That is, in the package of the first LED module (M1) or in the package of the driving chip (C), the M pins (P) are arranged around the first side (S1) such that an average of distances to the first side (S1) is a smallest among the averages of the distances between the M pins (P) and each of the first side (S1) to the fourth side (S4). Specifically, the distances between each of the M pins (P) and the first side (S1) are calculated, and an average of the calculated distances is smaller than an average of the distances between each of the M pins (P) and the other sides.

Moreover, first N pins (P) for outputting first N column driving signals (SIG(D)) among the K×N pins (P) are arranged around the second side (S2) such that an average of distances to the second side (S2) is a smallest among the averages of distances between the first N pins (P) and each of the first side (S1) to the fourth side (S4).

In addition, second N pins (P) for outputting second N column driving signals (SIG(D)) among the K×N pins (P) are arranged around the fourth side (S4) such that an average of the distances to the fourth side (S4) is a smallest among the averages of the distances between the second N pins (P) and each of the first side (S1) to the fourth side (S4).

In the LED display device 200 according to the second embodiment, like the LED display device 100 according to the first embodiment, a group unit including the corresponding first LED module (M1) and the K second LED modules (M2) is repeatedly arranged in the form of a block. For example, the group unit including the corresponding first LED module (M1) and the K second LED modules (M2) is repeatedly arranged in the shape of the English alphabet capital letter “T” or “T” rotated 180 degrees. That is, in the LED display device 200 according to the second embodiment, group units each including the corresponding first LED module (M1) and the K second LED modules (M2) are arranged like fitting puzzle pieces together.

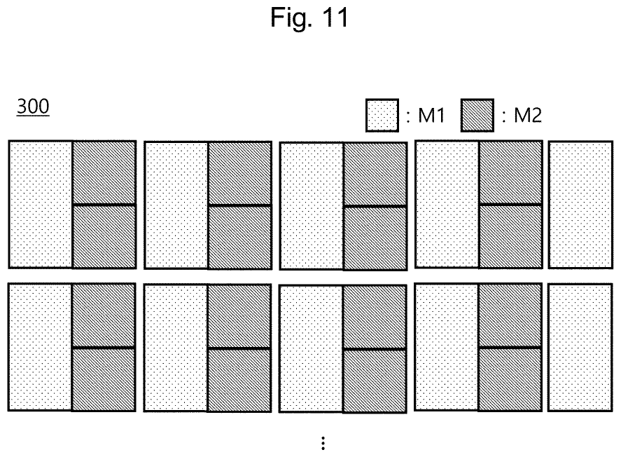

FIG. 11 is an explanatory view illustrating an arrangement of the plurality of LED modules in the display device 300 according to a third embodiment.

The display device 300 including the plurality of LED modules (M1, M2) according to the third embodiment includes the characteristics of the display device 200 including the plurality of LED modules (M1, M2) according to the second embodiment described above, unless otherwise described.

However, in the display device 300 including the plurality of LED modules (M1, M2) according to the third embodiment, one side of the second side (S2) to the fourth side (S4) is divided into upper and lower portions, and N pins (P) are arranged on each portion. In this case, in the LED display device 300 according to the third embodiment, a group unit including the corresponding first LED module (M1) and the K second LED modules (M2) is repeatedly arranged in the form of a block. For example, the group unit including the corresponding first LED module (M1) and the K second LED modules (M2) is repeatedly arranged in a rectangular form.

According to the display devices 100, 200, and 300 including the plurality of LED modules (M1, M2) according to the first embodiment to the third embodiment, the plurality of modules (M1, M2) are grouped as one in driving the LED display devices 100, 200, and 300, where only one LED module (M1) is provided with the driving chip (C) and the remaining LED modules (M2) are not provided with the driving chip (C). This makes it economical since the LED module (M1) provided with the driving chip (C) drives the remaining LED modules (M2) not provided with the driving chips (C), thereby reducing the number of driving chips (C).

Moreover, the configuration of the driving chip (C) is economical in terms of overall material cost, as it contributes to improving the integration density of the driving chip (C) by being arranged in only some LED modules (M1), compared to providing functions required for driving the plurality of LEDs (L) in each LED module (M1, M2).

As described above, according to the display devices 100, 200, and 300 including the plurality of LED modules (M1, M2) according to the first embodiment to the third embodiment, it is possible to optimize the arrangement of the driving chip (C) for driving the LEDs (L) and reduce the cost.

What is claimed is:

1. A LED display device, the device comprising:
a plurality of first LED modules, each including an LED array in which U×V LEDs are arranged; and
a plurality of second LED modules, each including an LED array in which M×N LEDs are arranged,
wherein U, M, V, and N are each a natural number equal to or greater than 5, wherein U and M are equal to or different from each other, and wherein V and N are equal to or different from each other.

2. The device of claim 1, wherein each of the plurality of first LED modules includes a driving chip, and wherein at least some of the driving chips provided in the plurality of first LED modules drive an LED array included in a corresponding first LED module and LED arrays included in K second LED modules, where K is a natural number equal to or greater than 1.

3. The device of claim 2, wherein a package of the first LED module or a package of the driving chip has a rectangular shape with four sides in a plan view, and includes M pins for outputting M row-scan switch signals and K×N pins for outputting K×N column driving signals, on a bottom surface.

4. The device of claim 3, wherein the package of the first LED module or the package of the driving chip is configured such that an average of distances to one side is a smallest among averages of distances between the M pins and each of the four sides.

5. The device of claim 4, wherein an average of distances to another side is a smallest among averages of distances between N pins for outputting first N column driving signals among the K×N pins and each of the four sides.

6. The device of claim 2, wherein each of the K second LED modules is arranged adjacent to one of a plurality of sides of a package of the corresponding first LED module or a package of the corresponding driving chip.

7. The device of claim 3, wherein each of the plurality of second LED modules has a rectangular shape in a plan view, and includes M pins for receiving the M row-scan switch signals and N pins for receiving the N column driving signals.

8. The device of claim 2, wherein U and M are equal to each other, wherein V and N are equal to each other, and wherein each of the plurality of first LED modules and each of the plurality of second LED modules have an identical external appearance in a top view.

9. The device of claim 2, wherein each size of the plurality of first LED modules corresponds to 1 time or Y times each size of the plurality of second LED modules in a top view, where Y is a natural number equal to or greater than 2.

10. The device of claim 2, wherein each of the K second LED modules is arranged adjacent to the corresponding first LED module, and wherein the LED display device is configured such that a group unit including the corresponding first LED module and the K second LED modules is repeatedly arranged in the form of a block.

11. The device of claim 2, wherein a group unit including the corresponding first LED module and the K second LED modules is repeatedly arranged in the shape of the English alphabet capital letter “T” or “T” rotated 180 degrees.
